(19) United States
(12) Patent Application Publication
(10) Pub. No.: US 2023/0403890 A1
(43) Pub. Date: Dec. 14, 2023

(54) DISPLAY DEVICE AND METHOD OF MANUFACTURING THE SAME

(71) Applicant: Samsung Display Co., Ltd., Yongin-si (KR)

(72) Inventors: YOUNGOK PARK, Seoul (KR); WONCHUL SHIN, Asan-si (KR); CHUNGHAN SHIM, Cheonan-si (KR); DONGHWAN LEE, Cheonan-si (KR); SANGYOUNG LIM, Asan-si (KR)

(21) Appl. No.: 18/100,208

(22) Filed: Jan. 23, 2023

(30) Foreign Application Priority Data
Jun. 14, 2022 (KR) 10-2022-0072125

(51) Int. Cl. H10K 59/124; H10K 59/12

(52) U.S. Cl. CPC H10K 59/124; H10K 59/1201

(57) ABSTRACT

A display device includes a base substrate, a first active pattern disposed on a base substrate, a second active pattern disposed on a first active pattern and including a material different from a material of a first active pattern, and an interlayer insulating layer disposed on a second active pattern and having Si—O bonds and Si—F bonds on a surface thereof, where a contact hole is defined through the interlayer insulating layer. The number of the Si—O bonds on the surface of the interlayer insulating layer is greater than the number of the Si—F bonds on the surface of the interlayer insulating layer.

This application claims priority to Korean Patent Application No. 10-2022-0072125, filed on Jun. 14, 2022, and all the benefits accruing therefrom under 35 U.S.C. § 119, the content of which in its entirety is herein incorporated by reference.

### BACKGROUND

### 1. Field

Embodiments of the invention relate to a display device and method of manufacturing the display device.

### 2. Description of the Related Art

A display device typically includes a display area and a non-display area. A pixel may be disposed in the display area, and a driver and a wiring for driving the pixel may be disposed in the non-display area. When static electricity instantaneously generated in a manufacturing process of the display device is charged through a substrate, insulating layers or transistors in the display device may be damaged.

### SUMMARY

Embodiments provide a display device in which defects due to static electricity are reduced.

Embodiments provide a method of manufacturing the display device.

A display device according to an embodiment includes a base substrate, a first active pattern disposed on the base substrate, a second active pattern disposed on the first active pattern and including a material different from material of the first active pattern, and an interlayer insulating layer disposed on the second active pattern and having Si—O bonds and Si—F bonds on a surface there, where a contact hole is defined through the interlayer insulating layer, and a number of the Si—O bonds on the surface of the interlayer insulating layer is greater than a number of the Si—F bonds on the surface of the interlayer insulating layer.

In an embodiment, the surface of the interlayer insulating layer may have hydrophilicity.

In an embodiment, a surface roughness, a surface energy, and a contact angle of the interlayer insulating layer may be determined based on a ratio of the Si—O bonds to the Si—F bonds.

In an embodiment, a root mean square of the surface roughness of the interlayer insulating layer may be about 0.1 nanometer (nm) or less, and a peak-to-valley value of the surface roughness of the interlayer insulating layer may be about 3.0 nm or less.

In an embodiment, the contact angle of the interlayer insulating layer may be about 16° or less.

In an embodiment, the interlayer insulating layer may include silicon nitride.

In an embodiment, the first active pattern may include a silicon semiconductor, and the second active pattern may include an oxide semiconductor.

A method of manufacturing a display device according to an embodiment includes providing a first active pattern on a base substrate, providing a second active pattern including a material different from a material of the first active pattern on the first active pattern, providing an interlayer insulating layer on the second active pattern, forming a contact hole through the interlayer insulating layer, and radiating ultraviolet rays on the interlayer insulating layer.

In an embodiment, the contact hole may be formed using an etching gas containing fluorine.

In an embodiment, a number of Si—F bonds on a surface of the interlayer insulating layer may increase while the contact hole is formed.

In an embodiment, the number of the Si—F bonds on the surface of the interlayer insulating layer may decrease and a number of Si—O bonds on the surface of the interlayer insulating layer may increase while the ultraviolet rays are radiated.

In an embodiment, the number of the Si—O bonds on the surface of the interlayer insulating layer may be greater than the number of the Si—F bonds on the surface of the interlayer insulating layer after the ultraviolet rays are radiated on the interlayer insulating layer.

In an embodiment, the surface of the interlayer insulating layer may have hydrophilicity after the ultraviolet rays are radiated on the interlayer insulating layer.

In an embodiment, a surface roughness, a surface energy, and a contact angle of the interlayer insulating layer may decrease after the ultraviolet rays are radiated on the interlayer insulating layer.

In an embodiment, an increase of the number of the Si—O bonds on the surface of the interlayer insulating layer may be derived from an ambient air.

In an embodiment, the ultraviolet rays may have a wavelength in a range of about 140 nm to about 180 nm.

In an embodiment, the base substrate may be disposed on a carrier substrate, and the carrier substrate may be moved by a roller while the ultraviolet rays are radiated on the interlayer insulating layer, and the average amount of static electricity generated by friction between the carrier substrate and the roller may be about 300 volts (V) or less.

In an embodiment, the carrier substrate may move at a speed in a range of about 4 meters per minute (m/min) to about 6 m/min by the roller, and the ultraviolet rays may be radiated for about 5 seconds to about 10 seconds.

In an embodiment, the surface of the interlayer insulating layer may be rinsed with distilled water after the ultraviolet rays are radiated on the interlayer insulating layer.

As described herein, the display device according to embodiments of the invention may include the interlayer insulating layer having the Si—O bonds and the Si—F bonds on a surface, and the number of the Si—O bonds may be greater than the number of the Si—F bonds on the surface of the interlayer insulating layer. Accordingly, the amount of static electricity generated in the manufacturing process of the display device may be reduced, and defects of the display device due to the static electricity may be reduced.

In addition, according to the method of manufacturing the display device according to embodiments of the invention, after the contact holes penetrating the interlayer insulating layer are formed, the ultraviolet rays may be radiated on the interlayer insulating layer. Accordingly, the number of the Si—O bonds may be greater than the number of the Si—F bonds on the surface of the interlayer insulating layer. Accordingly, the amount of static electricity may be reduced, and defects of the display device due to the static electricity may be reduced.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a circuit diagram of the pixel included in the display device of FIG. 1.

FIG. 3 is a cross-sectional view illustrating the display device of FIG. 1.

FIG. 4 is an enlarged view of a surface of the interlayer insulating layer included in the display device of FIG. 3.

FIGS. 5 to 13 are cross-sectional views illustrating a method of manufacturing the display device of FIG. 3.

FIG. 14 is a cross-sectional view illustrating a step of a method of manufacturing a display device according to an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

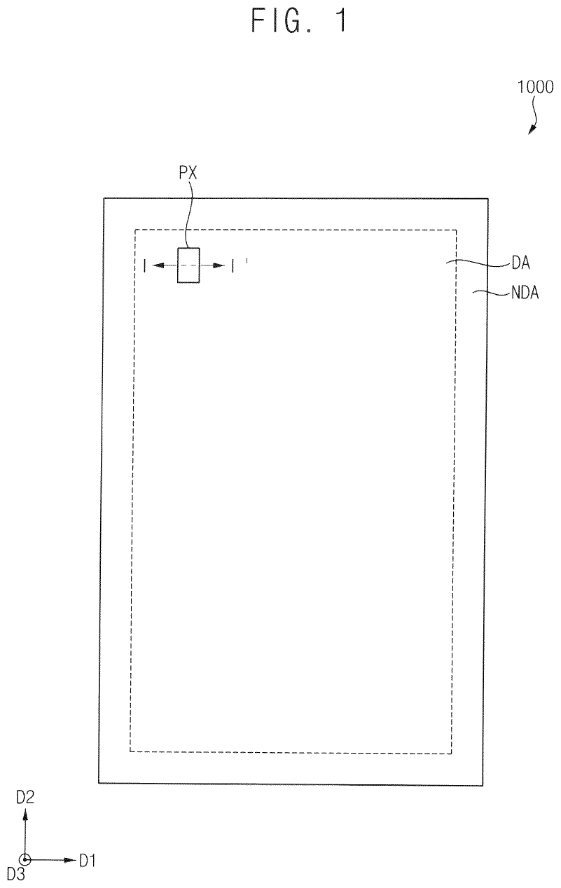

FIG. 1 is a plan view illustrating a display device according to an embodiment.

Referring to FIG. 1, a display device 1000 according to an embodiment may be divided into a display area DA and a non-display area NDA. In an embodiment, the non-display area NDA may be disposed around the display area DA. In an embodiment, for example, the non-display area NDA may surround the display area DA.

In an embodiment, the display device 1000 may have a rectangular shape on a plane. However, the invention is not limited thereto, and the display device 1000 may have various shapes. Here, the plane may be defined from a first direction D1 and a second direction D2 intersecting the first direction D1. The third direction D3 may be perpendicular to the plane or a thickness direction of the display device 1000.

At least one pixel PX may be disposed in the display area DA, and an image may be displayed through the pixel PX in the display area DA. Drivers for driving the pixel PX may be disposed in the non-display area NDA. The drivers may provide a signal and/or a voltage to the pixel PX. The pixel PX may emit light in response to the signal and/or the voltage.

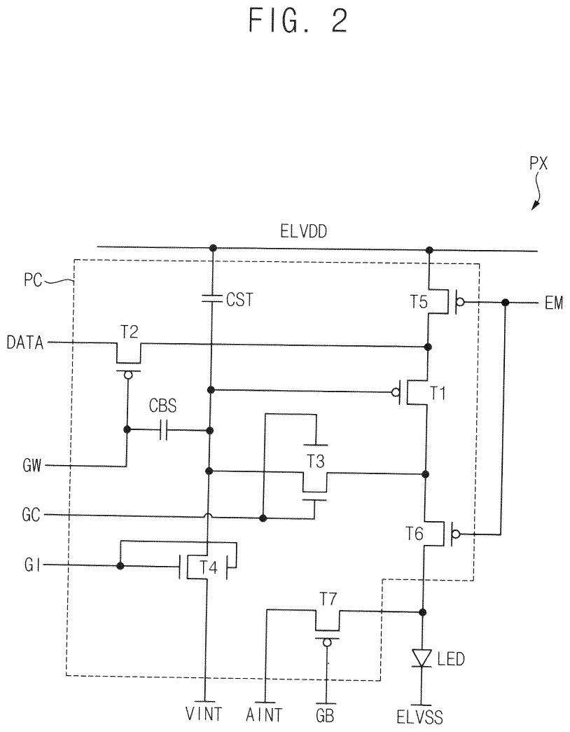

FIG. 2 is a circuit diagram of the pixel included in the display device of FIG. 1.

Referring to FIG. 2, an embodiment of the pixel PX may include a pixel circuit PC and a light emitting diode LED. The pixel circuit PC may provide a driving current to the light emitting diode LED. The light emitting diode LED may generate a light based on the driving current.

The pixel circuit PC may include a first transistor T1, a second transistor T2, a third transistor T3, a fourth transistor T4, a fifth transistor T5, a sixth transistor T6, and a seventh transistor T6, a transistor T7, a storage capacitor CST, and a boosting capacitor CBS.

The light emitting diode LED may include a first terminal (e.g., an anode terminal) and a second terminal (e.g., a cathode terminal), where the first terminal of the light emitting diode LED may be connected to the sixth transistor T6 and the seventh transistor T7, and the second terminal of the light emitting diode LED may receive a common voltage ELVSS. The light emitting diode LED may generate a light having a luminance corresponding to the driving current.

The storage capacitor CST may include a first terminal and a second terminal. The first terminal of the storage capacitor CST may be connected to the first transistor T1, and the second terminal of the storage capacitor CST may receive the driving voltage ELVDD. The storage capacitor CST may maintain the voltage level of the gate terminal of the first transistor T1 during an inactive period of the first gate signal GW.

The boosting capacitor CBS may include a first terminal and a second terminal. The first terminal of the boosting capacitor CBS may be connected to the gate terminal of the first transistor T1, and the second terminal of the boosting capacitor CBS may receive the first gate signal GW. The boosting capacitor CBS may compensate for the voltage drop of the gate terminal by increasing the voltage of the gate terminal of the first transistor T1 at the point in time when the supply of the first gate signal GW is stopped.

The first transistor T1 may include the gate terminal, a first terminal, and a second terminal. The gate terminal of the first transistor T1 may be connected to the first terminal of the storage capacitor CST. The first terminal of the first transistor T1 may be connected to the second transistor T2 and may receive the data voltage DATA. The second terminal of the first transistor T1 may be connected to the sixth transistor T6. The first transistor T1 may generate the driving current based on a voltage difference between the gate terminal and the first terminal. In an embodiment, for example, the first transistor T1 may be referred to as a driving transistor.

The second transistor T2 may include a gate terminal, a first terminal, and a second terminal. The gate terminal of the second transistor T2 may receive the first gate signal GW.

The second transistor T2 may be turned on or off in response to the first gate signal GW. In an embodiment, for example, where the second transistor T2 is a p-type transistor, e.g., a p-channel metal-oxide-semiconductor (PMOS) transistor, the second transistor T2 may be turned off when the first gate signal GW has a positive voltage level, and turned on when the first gate signal GW has a negative voltage level. The first terminal of the second transistor T2 may receive the data voltage DATA. The second terminal of the second transistor T2 may provide the data voltage DATA to the first terminal of the first transistor T1 while the second transistor T2 is turned on. In an embodiment, for example, the second transistor T2 may be referred to as a switching transistor.

The third transistor T3 may include a gate terminal, a lower gate terminal, a first terminal, and a second terminal. The gate terminal and the lower gate terminal of the third transistor T3 may receive a second gate signal GC. The first terminal of the third transistor T3 may be connected to the second terminal of the first transistor T1. The second terminal of the third transistor T3 may be connected to the gate terminal of the first transistor T1.

During a period in which the third transistor T3 is turned on in response to the second gate signal GC, the third transistor T3 may diode-connect the first transistor T1. Accordingly, the third transistor T3 may compensate for the threshold voltage of the first transistor T1. In an embodiment, for example, the third transistor T3 may be referred to as a compensation transistor.

The fourth transistor T4 may include a gate terminal, a lower gate terminal, a first terminal, and a second terminal. The gate terminal and the lower gate terminal of the fourth transistor T4 may receive a third gate signal GI. The first terminal of the fourth transistor T4 may be connected to the gate terminal of the first transistor T1. The second terminal of the fourth transistor T4 may receive a gate initialization voltage VINT.

The fourth transistor T4 may be turned on or off in response to the third gate signal GI. In an embodiment, for example, where the fourth transistor T4 is an n-type transistor, e.g., an n-channel metal-oxide-semiconductor (NMOS) transistor, the fourth transistor T4 may be turned on when the third gate signal GI has a positive voltage level, and turned off when the third gate signal GI has a negative voltage level.

During a period in which the fourth transistor T4 is turned on to the third gate signal GI, a gate initialization voltage VINT may be provided to the gate terminal of the first transistor T1. Accordingly, the fourth transistor T4 may initialize the gate terminal of the first transistor T1 to the gate initialization voltage VINT. In an embodiment, for example, the fourth transistor T4 may be referred to as a gate initialization transistor.

The fifth transistor T5 may include a gate terminal, a first terminal, and a second terminal. The gate terminal of the fifth transistor T5 may receive an emission control signal EM. The first terminal of the fifth transistor T5 may receive a driving voltage ELVDD. The second terminal of the fifth transistor T5 may be connected to the first transistor T1. When the fifth transistor T5 is turned on in response to the emission control signal EM, the fifth transistor T5 may provide the driving voltage ELVDD to the first transistor T1.

The sixth transistor T6 may include a gate terminal, a first terminal, and a second terminal. The gate terminal of the sixth transistor T6 may receive the emission control signal EM. The first terminal of the sixth transistor T6 may be connected to the first transistor T1. The second terminal of the sixth transistor T6 may be connected to the light emitting diode LED. When the sixth transistor T6 is turned on in response to the emission control signal EM, the sixth transistor T6 may provide the driving current to the light emitting diode LED.

The seventh transistor T7 may include a gate terminal, a first terminal, and a second terminal. The gate terminal of the seventh transistor T7 may receive the fourth gate signal GB. The first terminal of the seventh transistor T7 may be connected to the light emitting diode LED. The second terminal of the seventh transistor T7 may receive an anode initialization voltage AINT.

When the seventh transistor T7 is turned on in response to the fourth gate signal GB, the seventh transistor T7 may provide the anode initialization voltage AINT to the light emitting diode LED. Accordingly, the seventh transistor T7 may initialize the first terminal of the light emitting diode LED to the anode initialization voltage AINT. In an embodiment, for example, the seventh transistor T7 may be referred to as an anode initialization transistor.

In an embodiment, some of the first to seventh transistors T1, T2, T3, T4, T5, T6, and T7 may be PMOS transistors, and the other transistors may be NMOS transistors. In an embodiment, the first, second, fifth, sixth, and seventh transistors T1, T2, T5, T6, T7 may be PMOS transistors, and the third and fourth transistors T3, T4 may be NMOS transistors. Accordingly, the first active pattern of the PMOS transistors may include a cation-doped silicon semiconductor, and the second active pattern of the NMOS transistors may include an oxide semiconductor. In such an embodiment, the first gate signal GW for turning on the second, fifth, sixth, and seventh transistors T2, T5, T6, and T7, the emission control signal EM, and the fourth gate signal GB may have a negative voltage level, and the second gate signal GC for turning on the third and fourth transistors T3 and T4, and the third gate signal GI may have a positive voltage level.

However, the invention is not limited thereto, and in an alternative embodiment, the first, second, fifth, and sixth transistors T1, T2, T5, and T6 may be PMOS transistors, and the third, fourth and seventh transistors T3, T4, and T7 may be NMOS transistors. In another alternative embodiment, only one of the first to seventh transistors T1, T2, T3, T4, T5, T6, and T7 may be an NMOS transistor, and the other transistors may be PMOS transistors.

It would be understood that the circuit structure of the pixel circuit PC illustrated in FIG. 2 is merely exemplary and may be variously changed.

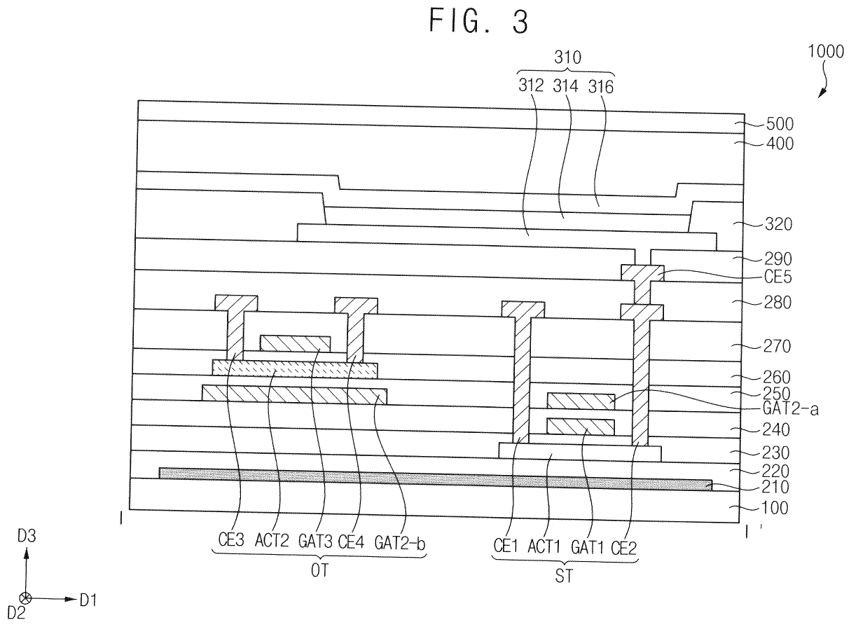

FIG. 3 is a cross-sectional view illustrating the display device of FIG. 1. More particularly, FIG. 3 is a cross-sectional view taken along line I-I′ of FIG. 1.

Referring to FIG. 3, an embodiment of the display device 1000 may include a base substrate 100, a back metal layer 210, a buffer layer 220, a first insulating layer 230, a second insulating layer 240, a third insulating layer 250, a fourth insulating layer 260, an interlayer insulating layer 270, a first via insulating layer 280, a second via insulating layer 290, a silicon transistor ST, an oxide transistor OT, a light emitting device 310, a pixel defining layer 320, an encapsulation layer 400, and a window 500.

The base substrate 100 may include a transparent material or an opaque material. In an embodiment, for example, the material of the base substrate 100 may include glass, quartz, plastic, or the like. These may be used alone or in combination with each other. In addition, the base substrate 100 may be configured as (or defined by) a single layer or a multi-layer in combination with each other.

The back metal layer 210 may be disposed on the base substrate 100. In an embodiment, the back metal layer 210 may include or be formed of a metal, an alloy, a conductive metal oxide, a transparent conductive material, or the like. In an embodiment, for example, the material of the back metal layer 210 may include silver (Ag), an alloy containing silver, molybdenum (Mo), an alloy containing molybdenum, aluminum (Al), an alloy containing aluminum, and aluminum nitride (AlN). ), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. In addition, the back metal layer 210 may be configured as a single layer or as a multi-layer in combination with each other.

The buffer layer 220 may be disposed on the base substrate 100 to cover the back metal layer 210. In an embodiment, the buffer layer 220 may include or be formed of an inorganic insulating material. In an embodiment, for example, the material of the inorganic insulating material may include silicon oxide, silicon nitride, silicon oxynitride, or the like. These may be used alone or in combination with each other. The buffer layer 220 may prevent metal atoms or impurities from diffusing from the base substrate 100 into a first active pattern ACT1. In addition, the buffer layer 220 may control a heat supply rate during a crystallization process for forming the first active pattern ACT1.

In an alternative embodiment, a barrier layer (not shown) may be additionally disposed on the back metal layer 210 and/or under the back metal layer 210. In such an embodiment, the barrier layer may be additionally disposed between the back metal layer 210 and the base substrate 100 and/or between the back metal layer 210 and the buffer layer 220. The barrier layer may include or be formed of an organic insulating material and/or an inorganic insulating material.

The first active pattern ACT1 may be disposed on the buffer layer 220. In an embodiment, the first active pattern ACT1 may include a silicon semiconductor. In an embodiment, for example, the silicon semiconductor of the first active pattern ACT1 may include amorphous silicon, polycrystalline silicon, or the like. These may be used alone or in combination with each other.

The first insulating layer 230 may be disposed on the buffer layer 220 to cover the first active pattern ACT1. In an embodiment, the first insulating layer 230 may include or be formed of an insulating material. In an embodiment, for example, the insulating material of the first insulating layer 230 may include silicon oxide, silicon nitride, silicon oxynitride, or the like. These may be used alone or in combination with each other.

A first gate electrode GAT1 may be disposed on the first insulating layer 230. The first gate electrode GAT1 may overlap the first active pattern ACT1. In an embodiment, the first gate electrode GAT1 may include or be formed of a metal, an alloy, a conductive metal oxide, a transparent conductive material, or the like. In an embodiment, for example, a material of the first gate electrode GAT1 may include silver (Ag), an alloy containing silver, molybdenum (Mo), an alloy containing molybdenum, aluminum (Al), an alloy containing aluminum, and aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second insulating layer 240 may be disposed on the first insulating layer 230 to cover the first gate electrode GAT1. In an embodiment, the second insulating layer 240 may include or be formed of an insulating material. In an embodiment, for example, the insulating material of the second insulating layer 240 may include silicon oxide, silicon nitride, silicon oxynitride, or the like. These may be used alone or in combination with each other.

The second gate electrode GAT2-a and the lower gate electrode GAT2-b may be disposed on the second insulating layer 240. The second gate electrode GAT2-a may overlap the first gate electrode GAT1, and the lower gate electrode GAT2-b may overlap a second active pattern ACT2. In an embodiment, the second gate electrode GAT2-a and the lower gate electrode GAT2-b may be disposed in or directly on a same layer as each other and spaced apart from each other.

The second gate electrode GAT2-a and the lower gate electrode GAT2-b may include or be formed of a metal, an alloy, a conductive metal oxide, a transparent conductive material, or the like. In an embodiment, for example, the materials of the second gate electrode GAT2-a and the lower gate electrode GAT2-b may include silver (Ag), an alloy containing silver, molybdenum (Mo), an alloy containing molybdenum, aluminum (Al), alloys containing aluminum, aluminum nitride (AlN), tungsten (W), tungsten nitride (WN), copper (Cu), nickel (Ni), chromium (Cr), chromium nitride (CrN), titanium (Ti) ), tantalum (Ta), platinum (Pt), scandium (Sc), indium tin oxide (ITO), indium zinc oxide (IZO), or the like. These may be used alone or in combination with each other.

The third insulating layer 250 may be disposed on the second insulating layer 240 to cover the second gate electrode GAT2-a and the lower gate electrode GAT2-b. In an embodiment, the third insulating layer 250 may include or be formed of an inorganic insulating material. In an embodiment, for example, the inorganic insulating material of the third insulating layer 250 may include silicon oxide, silicon nitride, silicon oxynitride, or the like. These may be used alone or in combination with each other.

The second active pattern ACT2 may be disposed on the third insulating layer 250. The second active pattern ACT2 may overlap the lower gate electrode GAT2-b. The second active pattern ACT2 may include an oxide semiconductor. In an embodiment, for example, the oxide semiconductor of the second active pattern ACT2 may be IGZO (InGaZnO), ITZO (InSnZnO), or the like. In addition, the oxide semiconductor may further include indium (In), gallium (Ga), tin (Sn), zirconium (Zr), vanadium (V), hafnium (Hf), cadmium (Cd), germanium (Ge), chromium (Cr), titanium (Ti), or zinc (Zn). These may be used alone or in combination with each other.

The fourth insulating layer 260 may be disposed on the third insulating layer 250 to cover the second active pattern ACT2. The fourth insulating layer 260 may include or be formed of an insulating material. In an embodiment, for example, the insulating material of the fourth insulating layer 260 may include silicon oxide, silicon nitride, silicon oxynitride, or the like. These may be used alone or in combination with each other.

A third gate electrode GAT3 may be disposed on the fourth insulating layer 260. The third gate electrode GAT3 may overlap the second active pattern ACT2. In an embodiment, the third gate electrode GAT3 may include or be formed of a metal, an alloy, a conductive metal oxide, a transparent conductive material, or the like. In an embodiment, for example, the material of the third gate electrode GAT3 may include silver (Ag), an alloy containing silver, molybdenum (Mo), an alloy containing molybdenum, aluminum (Al), an alloy containing aluminum, and aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The interlayer insulating layer 270 may be disposed on the fourth insulating layer 260 to cover the third gate electrode GAT3. In an embodiment, the interlayer insulating layer 270 may include or be formed of an inorganic insulating material. In an embodiment, for example, the interlayer insulating layer 270 may include silicon nitride.

In an embodiment, the interlayer insulating layer 270 may have a single-layer structure including silicon nitride. However, the invention is not limited thereto, and in an alternative embodiment, the interlayer insulating layer 270 may have a multilayer structure in which the uppermost layer includes silicon nitride. In an embodiment, for example, the interlayer insulating layer 270 may have a two-layer structure including a lower layer including silicon oxide and an upper layer including silicon nitride.

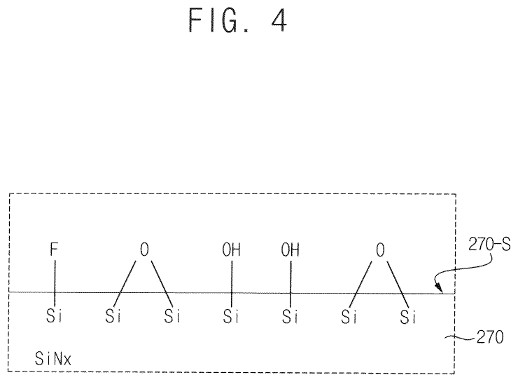

FIG. 4 is an enlarged view of a surface of the interlayer insulating layer included in the display device of FIG. 3.

Referring to FIGS. 3 and 4, the interlayer insulating layer 270 may have a Si—O bond and a Si—F bond on a surface 270-S thereof. In an embodiment, the number of the Si—O bonds may be greater than the number of the Si—F bonds on the surface 270-S of the interlayer insulating layer 270. In such an embodiment, a ratio of the Si—O bonds to the Si—F bonds (Si—O/Si—F) may exceed 1 on the surface 270-S of the interlayer insulating layer 270. In such an embodiment where the number of the Si—O bonds is greater than the number of the Si—F bonds on the surface 270-S of the interlayer insulating layer 270, the surface 270-S of the interlayer insulating layer 270 may have hydrophilicity.

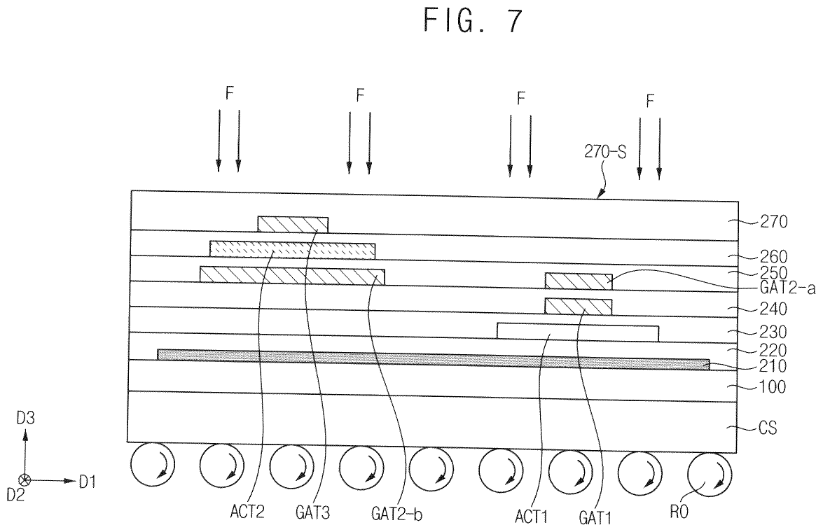

In an embodiment, the interlayer insulating layer 270 may be penetrated by a plurality of contact holes, that is, a plurality of contact holes is defined through the interlayer insulating layer 270, and the Si—F bond may be formed while the contact holes are formed. In such an embodiment, the ratio of the Si—O bond to the Si—F bond may be controlled by radiating ultraviolet rays to the surface 270-S of the interlayer insulating layer 270 after the contact holes are formed. This will be described later in greater detail with reference to FIGS. 7 to 11.

In such an embodiment where the number of the Si—O bonds is greater than the number of the Si—F bonds on the surface 270-S of the interlayer insulating layer 270, the amount of static electricity generated in the manufacturing process of the display device 1000 may be reduced. Accordingly, defects in the display device 1000 due to the static electricity may be reduced. In an embodiment, the static electricity may be generated by a friction between a carrier substrate that supports the base substrate 100 and a roller that moves the carrier substrate.

In an embodiment, the physical properties of the surface 270-S of the interlayer insulating layer 270 may be changed according to (or determined based on) the ratio of the Si—O bond to the Si—F bond. In an embodiment, for example, as the ratio of the Si—O bond to the Si—F bond changes, a surface roughness, a surface energy, and a contact angle of the interlayer insulating layer 270 may be changed. In an embodiment, as the ratio of the Si—O bond to the Si—F bond increases, the surface roughness, the surface energy, and the contact angle of the interlayer insulating layer 270 may decrease.

In an embodiment, the root-mean-square (Rq) of the surface roughness of the interlayer insulating layer 270 may be about 0.1 nanometer (nm) or less, and the peak-to-valley (PVT) value of the surface roughness of the interlayer insulating layer 270 may be about 3.0 nm or less. In an embodiment, for example, the root-mean-square (Rq) of the surface roughness of the interlayer insulating layer 270 may be in a range of about 0.001 nm to about 0.1 nm, and the peak-to-valley (PVT) value of the surface roughness of the interlayer insulating layer 270 may be in a range of about 0.1 nm to about 3.0 nm. In such an embodiment, the peak-to-valley (PVT) value may mean a height difference between the highest point and the lowest point of the surface 270-S of the interlayer insulating layer 270. In such an embodiment where the surface roughness of the interlayer insulating layer 270 satisfies the above-described range, defects in the display device 1000 due to the static electricity generated in the manufacturing process of the display device 1000 may be further reduced.

In an embodiment, the surface energy of the interlayer insulating layer 270 may be about 25 joules per square meter (J/m²) or less. In an embodiment, for example, the surface energy of the interlayer insulating layer 270 may be about 0.1 J/m² to about 25 J/m². In such an embodiment where the surface roughness of the interlayer insulating layer 270 satisfies the above-described range, defects in the display device 1000 due to the static electricity generated in the manufacturing process of the display device 1000 may be further reduced.

In an embodiment, the contact angle of the interlayer insulating layer 270 may be about 16° or less. In an embodiment, for example, the contact angle of the interlayer insulating layer 270 may be in a range of about 1° to about 16°. In such an embodiment where the contact angle of the interlayer insulating layer 270 satisfies the above-described range, defects in the display device 1000 due to the static electricity generated in the manufacturing process of the display device 1000 may be further reduced.

Referring back to FIG. 3, first to fourth connection electrodes CE1, CE2, CE3, and CE4 may be disposed on the interlayer insulating layer 270. Each of the first connection electrode CE1 and the second connection electrode CE2 may be in contact with the first active pattern ACT1 through the contact holes defined through the first insulating layer 230, the second insulating layer 240, the third insulating layer 250, the fourth insulating layer 260, and the interlayer insulating layer 270. Each of the third connection electrode CE3 and the fourth connection electrode CE4 may be in contact with the second active pattern ACT2 through the contact holes defined through the fourth insulating layer 260, and the interlayer insulating layer 270.

In an embodiment, the first to fourth connection electrodes CE1, CE2, CE3, and CE4 may include or be formed of a metal, an alloy, a conductive metal oxide, a transparent conductive material, or the like. In an embodiment, for example, materials of the first to fourth connection electrodes CE1, CE2, CE3, and CE4 may include silver (Ag), an alloy containing silver, molybdenum (Mo), an alloy containing molybdenum, and aluminum (Al). ), alloys containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

In an embodiment, the first active pattern ACT1, the first gate electrode GAT1, the first connection electrode CE1, and the second connection electrode CE2 may constitute the silicon transistor ST. In an embodiment, for example, the silicon transistor ST may correspond to any one of the first transistor T1, the second transistor T2, the fifth transistor T5, the sixth transistor T6, and the seventh transistor T7 described above with reference to FIG. 2. In addition, the second active pattern ACT2, the lower gate electrode GAT2-b, the third gate electrode GAT3, the third connection electrode CE3, and the fourth connection electrode CE4 may constitute (or collectively define) the oxide transistor OT. In an embodiment, for example, the oxide transistor OT may correspond to any one of the third transistor T3 and the fourth transistor T4 described above with reference to FIG. 2. Also, the first gate electrode GAT1 and the second gate electrode GAT2-a may constitute a capacitor.

The first via insulating layer 280 may be disposed on the interlayer insulating layer 270 to cover the first to fourth connection electrodes CE1, CE2, CE3, and CE4. In an embodiment, a first via contact hole exposing a portion of the first connection electrode CE1 may be defined in the first via insulating layer 280. In an embodiment, the first via insulating layer 280 may include or be formed of an organic material. In an embodiment, for example, the organic material of the first via insulating layer 280 may include polyacrylic resin, polyimide resin, acrylic resin, or the like. These may be used alone or in combination with each other.

The fifth connection electrode CE5 may be disposed on the first via insulating layer 280. In an embodiment, the fifth connection electrode CE5 may be in contact with the first connection electrode CE1 through the first via contact hole defined in the first via insulating layer 280. In an embodiment, for example, the material of the fifth connection electrode CE5 may include silver (Ag), an alloy containing silver, molybdenum (Mo), an alloy containing molybdenum, aluminum (Al), an alloy containing aluminum, and aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second via insulating layer 290 may be disposed on the first via insulating layer 280 to cover the fifth connection electrode CE5. In an embodiment, a second via contact hole exposing a portion of the fifth connection electrode CE5 may be defined in the second via insulating layer 290. In an embodiment, the second via insulating layer 290 may include or be formed of an organic material. In an embodiment, for example, the organic material of the second via insulating layer 290 may include polyacrylic resins, polyimide-based resins, acrylic resins, or the like. These may be used alone or in combination with each other.

The light emitting device 310 and the pixel defining layer 320 may be disposed on the second via insulating layer 290.

The light emitting device 310 may include an anode electrode 312, a light emission layer 314, and a cathode electrode 316. In an embodiment, for example, the light emitting device 310 may correspond to the light emitting diode LED described with reference to FIG. 2.

The anode electrode 312 may be disposed on the second via insulating layer 290. The anode electrode 312 may be in contact with the fifth connection electrode CE5 through the second via contact hole defined through the second via insulating layer 290. Accordingly, the anode electrode 312 may be electrically connected to the silicon transistor ST through the fifth connection electrode CE5. In such an embodiment, the light emitting device 310 may be electrically connected to the silicon transistor ST through the fifth connection electrode CE5.

The pixel defining layer 320 may be disposed on the second via insulating layer 290. A pixel opening exposing a portion of the anode electrode 312 may be defined in the pixel defining layer 320. In an embodiment, the pixel defining layer 320 may include an organic material.

In an alternative embodiment, the fifth connection electrode CE5 and the second via insulating layer 290 may be omitted. In such an embodiment, the anode electrode 312 and the pixel defining layer 320 may be disposed on the first via insulating layer 280, and the anode electrode 312 may be in contact with the first connection electrode CE1 through the first via contact hole.

The emission layer 314 may be disposed on the anode electrode 312. In an embodiment, the emission layer 314 may be disposed on the anode electrode 312 exposed by the pixel opening. In an alternative embodiment, the emission layer 314 may be disposed on the anode electrode 312 and the pixel defining layer 320.

The cathode electrode 316 may be disposed on the emission layer 314. The emission layer 314 may emit light based on a voltage difference between the anode electrode 312 and the cathode electrode 316.

The encapsulation layer 400 may be disposed on the cathode electrode 316. The encapsulation layer 400 may protect the light emitting device 310 from impurities such as oxygen and moisture. In an embodiment, the encapsulation layer 400 may include at least one inorganic encapsulation layer and at least one organic encapsulation layer.

The window 500 may be disposed on the encapsulation layer 400. The window 500 may protect components disposed under the window 500. In an embodiment, the window 500 may include or be formed of glass, plastic, or the like.

According to embodiments, the display device 1000 may include the interlayer insulating layer 270, and the interlayer insulating layer 270 may have the Si—O bond and the Si—F bond on the surface 270-S, and the number of the Si—O bonds may be greater than the number of Si—F bonds on the surface 270-S of the interlayer insulating layer 270. In such an embodiment, the surface 270-S of the interlayer insulating layer 270 may have hydrophilicity. Accordingly, the amount of the static electricity generated in the manufacturing process of the display device 1000 may be reduced, and defects of the display device 1000 due to the static electricity may be reduced.

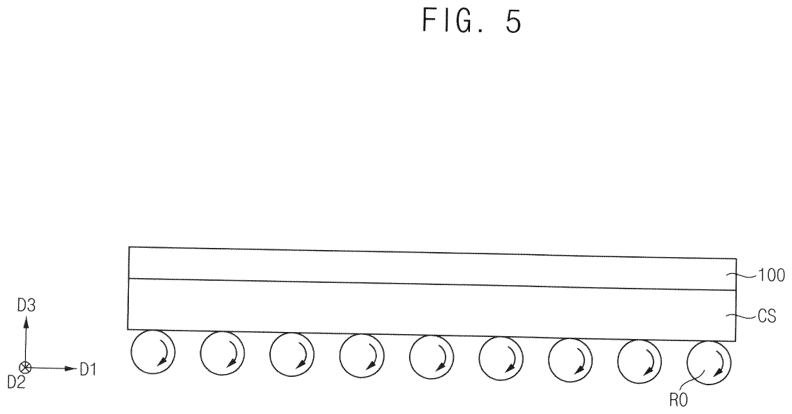

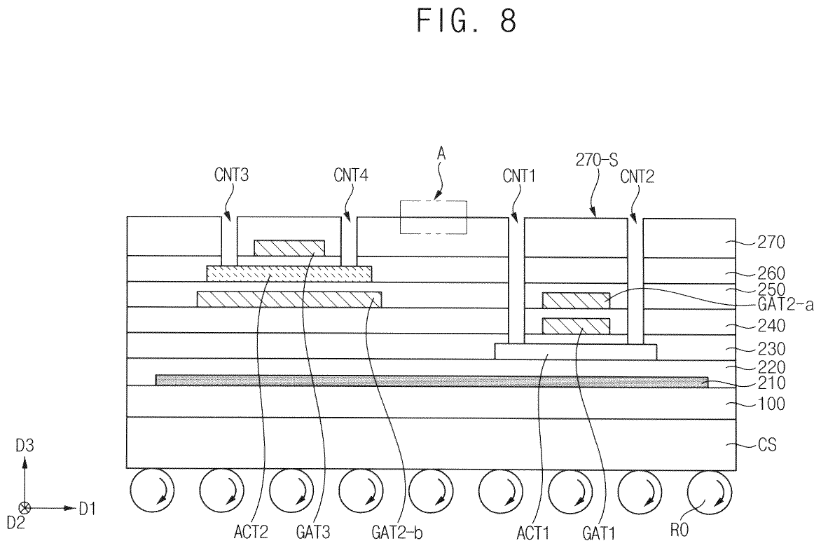

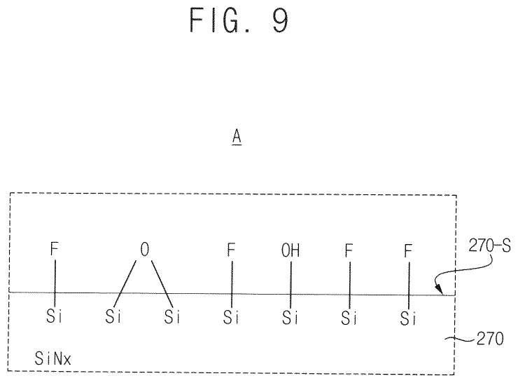

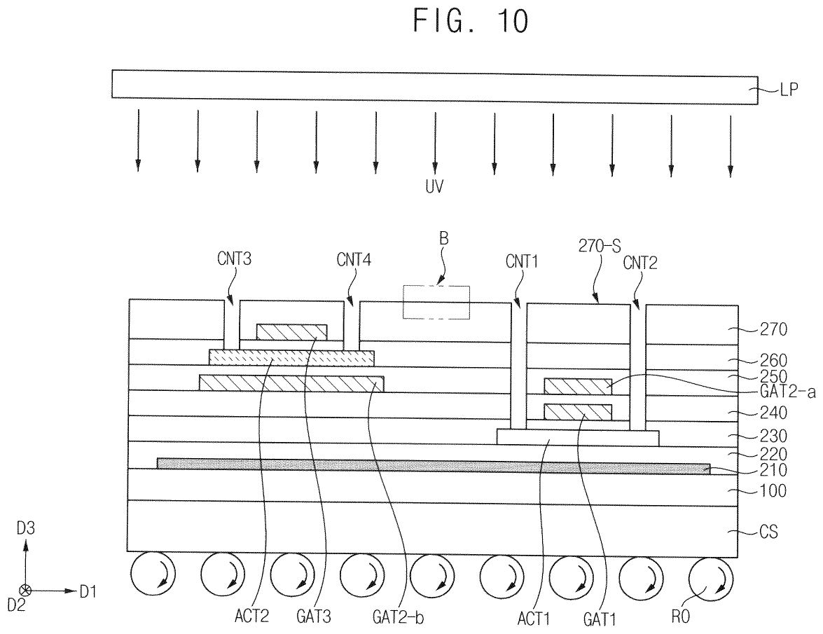

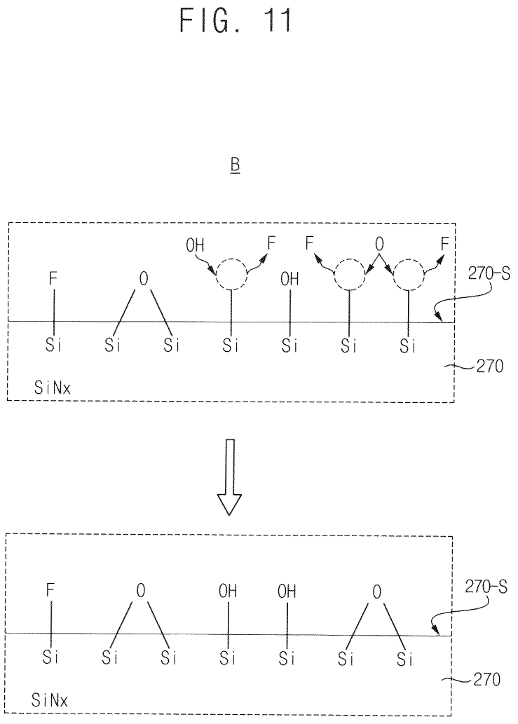

FIGS. 5 to 13 are cross-sectional views illustrating a method of manufacturing the display device of FIG. 3. More particularly, FIG. 9 is an enlarged view of area ‘A’ of FIG. 8, and FIG. 11 is an enlarged view of area ‘B’ of FIG. 10.

Referring to FIG. 5, a carrier substrate CS may be provided. The carrier substrate CS may support a plurality of components disposed on the carrier substrate CS in the manufacturing process of the display device 1000. In an embodiment, the carrier substrate CS may include a material having high rigidity and heat resistance. In an embodiment, for example, the material of the carrier substrate CS may include glass, quartz, or the like. These may be used alone or in combination with each other.

In an embodiment, during the manufacturing process of the display device 1000, the carrier substrate CS may directly contact a roller RO. In an embodiment, for example, the roller RO may move the carrier substrate CS in the manufacturing process of the display device 1000. In such an embodiment, in the manufacturing process of the display device 1000, the carrier substrate CS may move by the roller RO, and accordingly, the components disposed on the carrier substrate CS may move. In an embodiment, for example, when the roller RO rotates in a clockwise direction with respect to a rotation axis parallel to the second direction D2, the carrier substrate CS may move in the first direction D1, and accordingly, the components disposed on the carrier substrate CS may also move in the first direction D1.

In such a process, as the carrier substrate CS moves by the roller RO, the static electricity may be generated due to the friction between the carrier substrate CS and the roller RO. The static electricity may be charged to the components disposed on the carrier substrate CS, thereby causing a defect in the display device 1000.

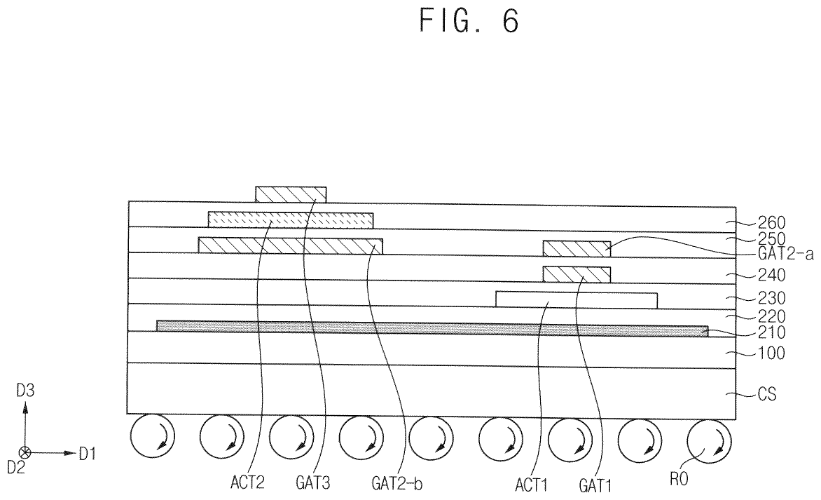

Referring to FIG. 6, the back metal layer 210 may be provided or formed on the base substrate 100, and the buffer layer 220 covering the back metal layer 210 may be provided or formed on the base substrate 100. The buffer layer 220 may prevent metal atoms or impurities from diffusing from the base substrate 100 into the first active pattern ACT1.

The first active pattern ACT1 may be provided or formed on the buffer layer 220. The first active pattern ACT1 may be provided or formed by forming a first active layer on the buffer layer 220 and then patterning the first active layer. In an embodiment, the first active layer may be a polycrystalline silicon film. The polycrystalline silicon film may be formed by forming an amorphous silicon film on the buffer layer 220 and then crystallizing the amorphous silicon.

The first insulating layer 230 covering the first active pattern ACT1 may be provided or formed on the buffer layer 220. The first gate electrode GAT1 may be provided or formed by forming a first gate layer on the first insulating layer 230 and patterning the first gate layer. The first gate electrode GAT1 may overlap the first active pattern ACT1.

The second insulating layer 240 covering the first gate electrode GAT1 may be provided or formed on the first insulating layer 230. A second gate layer may be provided or formed on the second insulating layer 240, and the second gate layer may be patterned to form the second gate electrode GAT2-a and the lower gate electrode GAT2-b. The second gate electrode GAT2-a may overlap the first active pattern ACT1, and the lower gate electrode GAT2-b may overlap the second active pattern ACT2.

The third insulating layer 250 covering the second gate electrode GAT2-a and the lower gate electrode GAT2-b may be provided or formed on the second insulating layer 240. Thereafter, the second active pattern ACT2 may be provided or formed on the third insulating layer 250. The second active pattern ACT2 may be provided or formed by forming a second active layer on the third insulating layer 250 and patterning the second active layer. In an embodiment, the second active layer may include IGZO (InGaZnO), ITZO (InSnZnO), or the like.

The fourth insulating layer 260 covering the second active pattern ACT2 may be provided or formed on the third insulating layer 250. The third gate electrode GAT3 may be provided or formed by forming a third gate layer on the fourth insulating layer 260 and patterning the third gate layer. The third gate electrode GAT3 may overlap the second active pattern ACT2.

Referring to FIGS. 7, 8, and 9, the interlayer insulating layer 270 covering the third gate electrode GAT3 may be provided or formed on the fourth insulating layer 260. A plurality of contact holes may be formed in the interlayer insulating layer 270. In an embodiment, for example, first to fourth contact holes CNT1, CNT2, CNT3, and CNT4 may be formed in or through the interlayer insulating layer 270.

In an embodiment, each of the first contact hole CNT1 and the second contact hole CNT2 may expose a portion of the first active pattern ACT1 by being formed through or penetrating the first insulating layer 230, the second insulating layer 240, the third insulating layer 250, the fourth insulating layer 260, the interlayer insulating layer 270. Each of the third contact hole CNT3 and the fourth contact hole CNT4 may expose a portion of the second active pattern ACT2 by being formed through or penetrating the third insulating layer 250, the fourth insulating layer 260, and the interlayer insulating layer 270.

In an embodiment, the first to fourth contact holes CNT1, CNT2, CNT3, and CNT4 may be formed using an etching gas containing fluorine. In such an embodiment, the first to fourth contact holes CNT1, CNT2, CNT3, and CNT4 may be formed by dry etching using the etching gas. Accordingly, in a process where the first to fourth contact holes CNT1, CNT2, CNT3, and CNT4 are formed, the surface 270-S of the interlayer insulating layer 270 may be exposed to the etching gas containing fluorine. In an embodiment, for example, the material of the etching gas may include sulfur hexafluoride (SF6), nitrogen trifluoride (NF3), or carbon tetrafluoride (CF4). These may be used alone or in combination with each other.

As shown in FIG. 9, in an embodiment, in a process where the first to fourth contact holes CNT1, CNT2, CNT3, and CNT4 are formed, the number of the Si—F bonds on the surface 270-S of the interlayer insulating layer 270 may increase. In such an embodiment, while the first to fourth contact holes CNT1, CNT2, CNT3, and CNT4 are formed, as the surface 270-S of the interlayer insulating layer 270 is exposed to the etching gas containing fluorine, the number of the Si—F bonds on the surface 270-S of the interlayer insulating layer 270 may increase. Accordingly, after the first to fourth contact holes CNT1, CNT2, CNT3, and CNT4 are formed, the surface 270-S of the interlayer insulating layer 270 may have hydrophobicity.

Referring to FIGS. 10 and 11, ultraviolet rays UV may be radiated on the interlayer insulating layer 270. In an embodiment, the ultraviolet rays UV may be radiated by an ultraviolet lamp (LP). In an embodiment, for example, the ultraviolet lamp LP may include a Xe-based lamp, a metal-halide-based lamp, a UV-based lamp, or a Mercury-based lamp. In an alternative embodiment, the ultraviolet rays UV may be radiated through a plasma treatment or the like that emits a light in the ultraviolet wavelength band.

In an embodiment, when the carrier substrate CS is moved by the roller RO, the ultraviolet rays UV may be radiated on the interlayer insulating layer 270. In an embodiment, for example, as the roller RO rotates in a clockwise direction with respect to the rotation axis parallel to the second direction D2, the carrier substrate CS may move in the first direction D1 and the ultraviolet rays UV may be radiated from the third direction D3.

In an embodiment, while the carrier substrate CS is moved by the roller RO at a speed of about 4 meters per minute (m/min) to about 6 m/min, the ultraviolet rays UV may be radiated on the interlayer insulating layer 270 for about 5 seconds to about 10 seconds. When the process of radiating the ultraviolet rays UV satisfies the above-described conditions, defects in the display device 1000 due to the static electricity generated in the manufacturing process of the display device 1000 may be further reduced.

As shown in FIG. 11, in an embodiment, while the ultraviolet rays UV are radiated on the interlayer insulating layer 270, the number of the Si—F bonds on the surface 270-S of the interlayer insulating layer 270 may be decreased. In such an embodiment, the energy of the ultraviolet rays UV may be greater than the bonding energy of the Si—F bonds. Accordingly, the number of the Si—F bonds may decrease, as the Si—F bonds are broken by the ultraviolet rays UV.

In an embodiment, the ultraviolet rays UV may have a wavelength in a range of about 140 nm to about 180 nm. However, the wavelength range of the ultraviolet rays UV is not particularly limited as long as the ultraviolet rays UV have sufficient energy to break the Si—F bonds.

In an embodiment, while the ultraviolet rays UV are radiated on the interlayer insulating layer 270, the number of the Si—O bonds on the surface 270-S of the interlayer insulating layer 270 may increase. In an embodiment, for example, an increase of the number of the Si—O bonds may be derived from an ambient air. In such an embodiment, as oxygen (O) or the like derived from the ambient air binds to Si instead of the Si—F bonds broken by the ultraviolet rays UV, the number of the Si—O bonds on the surface 270-S of the interlayer insulating layer 270 may increase.

Accordingly, after the ultraviolet rays UV are radiated on the interlayer insulating layer 270, the number of the Si—O bonds may be greater than the number of the Si—F bonds on the surface 270-S of the interlayer insulating layer 270. In an embodiment, the number of the Si—O bonds is greater than the number of the Si—F bonds on the surface 270-S of the interlayer insulating layer 270, the surface 270-S of the interlayer insulating layer 270 may have hydrophilicity. Accordingly, the amount of the static electricity generated in the manufacturing process of the display device 1000 may be reduced. Accordingly, defects in the display device 1000 due to the static electricity may be reduced.

In an embodiment, for example, where the number of the Si—O bonds is greater than the number of the Si—F bonds on the surface 270-S of the interlayer insulating layer 270, an average amount of charge of the static electricity generated by the friction between the carrier substrate CS and the roller RO may be about 300 volts (V) or less. In such an embodiment, the average amount of charge may be in a range of about 10 V to about 300 V. In such an embodiment where the average amount of charge satisfies the above-described range, defects in the display device 1000 due to the static electricity generated in the manufacturing process of the display device 1000 may be further reduced.

In an embodiment, as the ultraviolet rays UV are radiated on the interlayer insulating layer 270, the surface roughness, the surface energy, and the contact angle of the interlayer insulating layer 270 may be reduced. In such an embodiment, as the number of the Si—O bonds become greater than the number of the Si—F bonds on the surface 270-S of the interlayer insulating layer 270, the surface roughness, surface energy, and contact angle of the interlayer insulating layer 270 may be reduced. Accordingly, defects in the display device 1000 due to the static electricity generated in the manufacturing process of the display device 1000 may be further reduced.

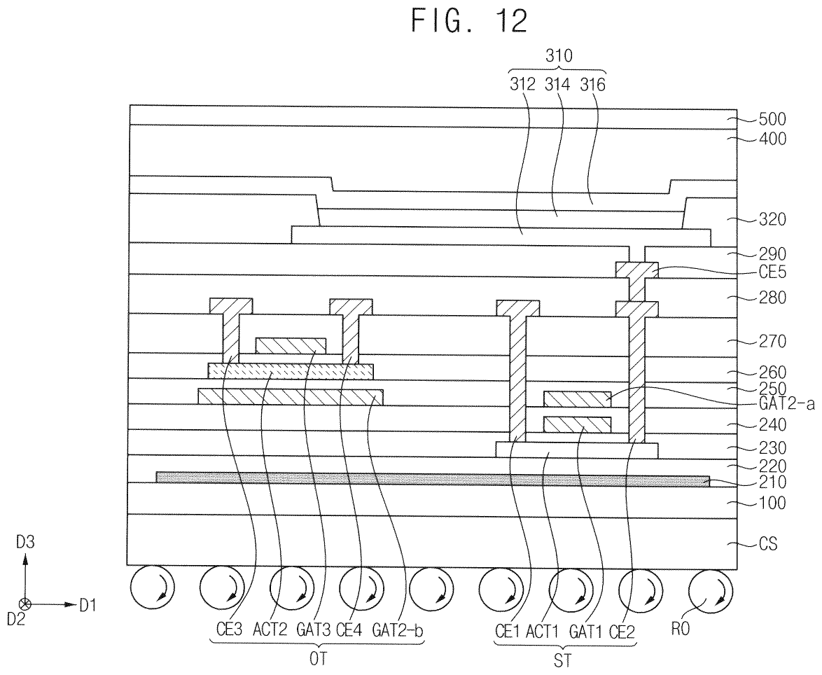

Referring to FIG. 12, the first to fourth connection electrodes CE1, CE2, CE3, and CE4 may be provided or formed on the interlayer insulating layer 270. Each of the first to fourth connection electrodes CE1, CE2, CE3, and CE4 may fill (or be disposed in) the first to fourth contact holes CNT1, CNT2, CNT3, and CNT4. In an embodiment, each of the first connection electrode CE1 and the second connection electrode CE2 may be in contact with the first active pattern ACT1 while filling the first contact hole CNT1 and the second contact hole CNT2, respectively. In addition, each of the third connection electrode CE3 and the fourth connection electrode CE4 may be in contact with the second active pattern ACT2 while filling the third contact hole CNT3 and the fourth contact hole CNT4, respectively.

Thereafter, the first via insulating layer 280 covering the first to fourth connection electrodes CE1, CE2, CE3, and CE4 may be provided or formed on the interlayer insulating layer 270. The first via contact hole exposing a portion of the first connection electrode CE1 may be defined in the first via insulating layer 280. Thereafter, the fifth connection electrode CE filling the first via contact hole may be formed. The fifth connection electrode CE5 may be in contact with the first connection electrode CE1, and may electrically connect the light emitting device 310 and the silicon transistor ST. Thereafter, the second via insulating layer 290 covering the fifth connection electrode CE5 may be provided or formed. The second via contact hole exposing a portion of the fifth connection electrode CE5 may be defined in the second via insulating layer 290. Thereafter, the anode electrode 312 filling the second via contact hole may be provided or formed. The anode electrode 312 may be electrically connected to the silicon transistor ST through the fifth connection electrode CE5.

Thereafter, the pixel defining layer 320 covering the anode electrode 312 may be provided or formed on the second via insulating layer 290. The pixel opening exposing a portion of the anode electrode 312 may be formed or defined in the pixel defining layer 320. Thereafter, the emission layer 314 may be formed on the anode electrode 312, and the cathode electrode 316 may be formed on the emission layer 314. The anode electrode 312, the light emission layer 314, and the cathode electrode 316 may constitute the light emitting device 310. Thereafter, the encapsulation layer 400 may be provided or formed on the light emitting device 310, and the window 500 may be provided or formed on the encapsulation layer 400.

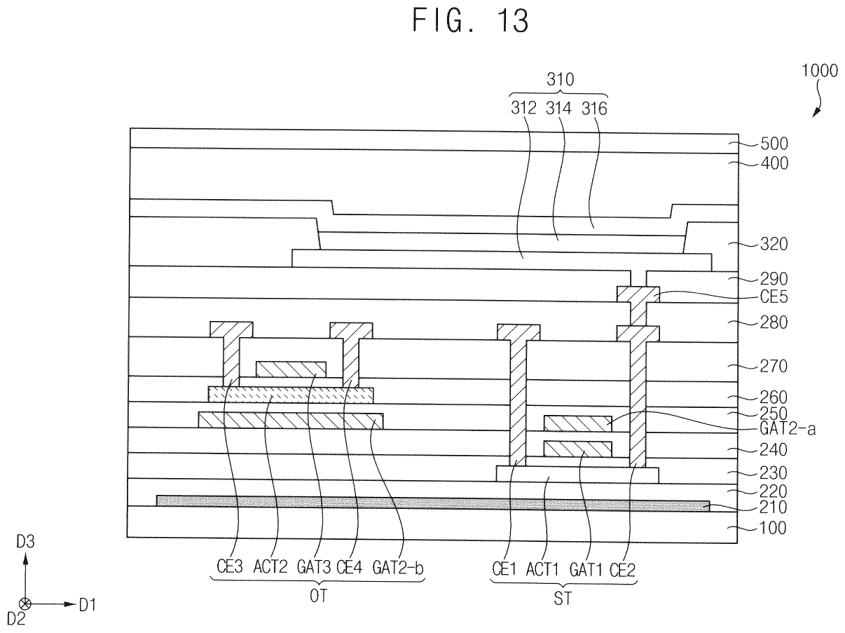

Referring to FIG. 13, the carrier substrate CS may be separated from the base substrate 100. Accordingly, the display device 1000 as shown in FIG. 3 may be provided.

According to embodiments, in the manufacturing process of the display device 1000, after forming contact holes through the interlayer insulating layer 270, the ultraviolet rays UV may be radiated on the interlayer insulating layer 270. Accordingly, the interlayer insulating layer 270 may have the Si—O bonds and the Si—F bonds on the surface 270-S, and the number of the Si—O bonds may be greater than the number of the Si—F bonds on the surface 270-S of the interlayer insulating layer 270. In such embodiments, the surface 270-S of the interlayer insulating layer 270 may have hydrophilicity. Accordingly, the amount of static electricity generated in the manufacturing process of the display device 1000 may be reduced, and defects of the display device 1000 due to the static electricity may be reduced.

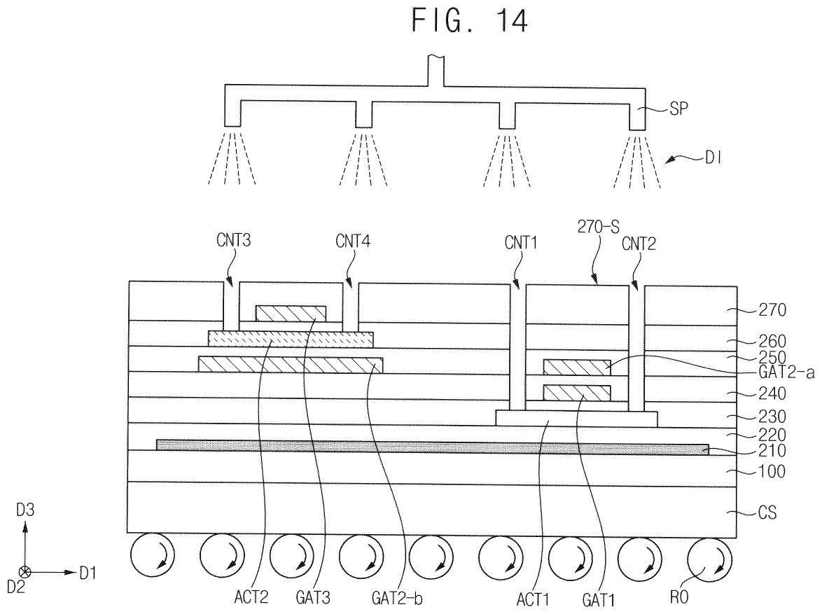

FIG. 14 is a cross-sectional view illustrating a step of a method of manufacturing a display device according to an alternative embodiment.

Referring to FIG. 14, in a method of manufacturing a display device according to an alternative embodiment of the invention, after radiating the ultraviolet rays UV of FIG. 10 on the interlayer insulating layer 270, the surface 270-S of the interlayer insulating layer 270 may be rinsed with distilled water DI.

In an embodiment, for example, the carrier substrate CS may be moved by the roller RO under a fixed spray SP, and the distilled water DI may be applied on the surface 270-S of the interlayer insulating layer 270 by the spray SP.

When the surface 270-S of the interlayer insulating layer 270 is rinsed with the distilled water DI, the Si—O bonds to replace the Si—F bonds broken by ultraviolet rays UV may be more smoothly formed. In addition, the Si—O bonds may be further increased by oxygen (O) or the like derived from the distilled water DI. Accordingly, the amount of the static electricity generated in the manufacturing process of the display device 1000 may be further reduced, and defects of the display device 1000 due to the static electricity may be further reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base substrate;
a first active pattern disposed on the base substrate;
a second active pattern disposed on the first active pattern and including a material different from a material of the first active pattern; and
an interlayer insulating layer disposed on the second active pattern and having Si—O bonds and Si—F bonds on a surface thereof, wherein a contact hole is defined through the interlayer insulating layer, and
wherein a number of the Si—O bonds on the surface of the interlayer insulating layer is greater than a number of the Si—F bonds on the surface of the interlayer insulating layer.

2. The display device of claim 1, wherein the surface of the interlayer insulating layer has hydrophilicity.

3. The display device of claim 2, wherein a surface roughness, a surface energy, and a contact angle of the interlayer insulating layer are determined based on a ratio of the Si—O bonds to the Si—F bonds.

4. The display device of claim 3, wherein
a root mean square of the surface roughness of the interlayer insulating layer is about 0.1 nm or less, and
a peak-to-valley value of the surface roughness of the interlayer insulating layer is about 3.0 nm or less.

5. The display device of claim 4, wherein the interlayer insulating layer has the surface energy of about 25 J/m² or less.

6. The display device of claim 5, wherein the contact angle of the interlayer insulating layer is about 160 or less.

7. The display device of claim 1, wherein the interlayer insulating layer includes silicon nitride.

8. The display device of claim 1, wherein
the first active pattern includes a silicon semiconductor, and
is the second active pattern includes an oxide semiconductor.

9. A method of manufacturing a display device, the method comprising:
providing a first active pattern on a base substrate;
providing a second active pattern including a material different from a material of the first active pattern on the first active pattern;
providing an interlayer insulating layer on the second active pattern;
forming a contact hole through the interlayer insulating layer; and
radiating ultraviolet rays on the interlayer insulating layer.

10. The method of claim 9, wherein the contact hole is formed using an etching gas containing fluorine.

11. The method of claim 10, wherein a number of Si—F bonds on a surface of the interlayer insulating layer increases while the contact hole is formed.

12. The method of claim 11, wherein the number of the Si—F bonds on the surface of the interlayer insulating layer decreases and a number of Si—O bonds on the surface of the interlayer insulating layer increases while the ultraviolet rays are radiated.

13. The method of claim 12, wherein the number of the Si—O bonds on the surface of the interlayer insulating layer is greater than the number of the Si—F bonds on the surface of the interlayer insulating layer after the ultraviolet rays are radiated on the interlayer insulating layer.

14. The method of claim 13, wherein the surface of the interlayer insulating layer has hydrophilicity after the ultraviolet rays are radiated on the interlayer insulating layer.

15. The method of claim 14, wherein a surface roughness, a surface energy, and a contact angle of the interlayer insulating layer decrease after the ultraviolet rays are radiated on the interlayer insulating layer.

16. The method of claim 13, wherein an increase of the number of the Si—O bonds on the surface of the interlayer insulating layer is derived from an ambient air.

17. The method of claim 9, wherein the ultraviolet rays have a wavelength in a range of about 140 nm to about 180 nm.

18. The method of claim 9, wherein
the base substrate is disposed on a carrier substrate, and
the carrier substrate is moved by a roller while the ultraviolet rays are radiated on the interlayer insulating layer, and
an average amount of static electricity generated by friction between the carrier substrate and the roller is about 300 V or less.

19. The method of claim 18, wherein
the carrier substrate moves at a speed in a range of about 4 m/min to about 6 m/min by the roller, and
the ultraviolet rays are radiated for about 5 seconds to about 10 seconds.

20. The method of claim 9, wherein a surface of the interlayer insulating layer is rinsed with distilled water after the ultraviolet rays are radiated on the interlayer insulating layer.
